(19) United States
(12) Patent Application Publication
(10) Pub. No.: US 2024/0324118 A1
(43) Pub. Date: Sep. 26, 2024

(54) Flexible Display Module and Display Device

(71) Applicants: MIANYANG BOE OPTOELECTRONICS TECHNOLOGY CO.,Ltd., Mianyang, Sichuan (CN); BOE Technology Group Co., Ltd., Beijing (CN)

(72) Inventors: Yongkai WU, Beijing (CN); Tingyuan WANG, Beijing (CN); Chao QI, Beijing (CN); Zhengping XIONG, Beijing (CN); Qi LIU, Beijing (CN); Yunzhi WANG, Beijing (CN)

(21) Appl. No.: 18/026,816

(22) PCT Filed: May 11, 2022
(86) PCT No.: PCT/CN2022/092199

§ 371 Date: Mar. 16, 2023

(51) Int. Cl. H05K 5/02; B32B 3/26; B32B 3/30; B32B 5/18; B32B 7/022; B32B 7/12; B32B 9/00; B32B 9/04; B32B 15/04; B32B 15/18; B32B 27/28; B32B 27/36

(52) U.S. Cl. CPC H05K 5/02; B32B 3/266; B32B 3/30; B32B 5/18; B32B 7/022; B32B 7/12; B32B 9/007; B32B 9/045; B32B 9/046; B32B 15/046; B32B 15/18; B32B 27/281; B32B 27/36; B32B 2255/10; B32B 2307/4023; B32B 2307/42; B32B 2307/536; B32B 2307/546; B32B 2307/7376; B32B 2457/20

(57) ABSTRACT

A flexible display module includes a flexible display substrate, a cover layer provided on a display side of the flexible display substrate, and a support layer on a side of the flexible display substrate facing away from the display side; the cover layer includes a first flexible film material and a first graphene layer on a surface of the first flexible film material facing away from the flexible display substrate; the support layer includes a rigid material layer and a first flexible material layer, the rigid material layer includes a hollowed region and non-hollowed regions located on two sides of the hollowed region, a width of the hollowed region is larger than a width of the bending region of the flexible display module, the first flexible material layer is provided on a surface of the rigid material layer facing the flexible display substrate and is filled in the hollowed region.

### CROSS-REFERENCE TO RELATED APPLICATION

The present application is a U.S. National Phase Entry of International Application PCT/CN2022/092199 having an international filing date of May 11, 2022, and entitled “Flexible Display Module and Display Device”. The entire contents of the above-identified application are hereby incorporated by reference.

### TECHNICAL FIELD

Embodiments of the present disclosure relate to, but are not limited to, the field of display technologies, and more particularly to a flexible display module and a display device.

### BACKGROUND

After some foldable display devices are used for a long time, flexible display modules are prone to die printing, creases and other problems, and peeling between film layers may easily occur in the bending process.

### SUMMARY

The following is a summary of subject matter described herein in detail. The summary is not intended to limit the protection scope of claims.

An embodiment of the present disclosure provides a flexible display module, the flexible display module includes a bending region and non-bending regions located on two sides of the bending region, wherein the flexible display module is folded and unfolded by bending of the bending region, and a bending axis of the bending region extends along a first direction; the flexible display module includes a flexible display substrate, a cover layer provided on a display side of the flexible display substrate, and a support layer provided on a side of the flexible display substrate facing away from the display side; the cover layer includes a first flexible film material and a first graphene layer provided on a surface of the first flexible film material facing away from the flexible display substrate; the support layer includes a rigid material layer and a first flexible material layer, the rigid material layer includes a hollowed region and non-hollowed regions located on two sides of the hollowed region, in a direction perpendicular to the first direction, a width of the hollowed region is larger than a width of the bending region, and the first flexible material layer is provided on a surface of the rigid material layer facing the flexible display substrate and filled in the hollowed region; or, the support layer includes a second flexible material layer and a second graphene layer provided on a surface of the second flexible material layer facing the flexible display substrate.

Other aspects may be understood upon reading and understanding of the drawings and the detailed description.

### BRIEF DESCRIPTION OF DRAWINGS

Accompanying drawings are intended to provide a further understanding of technical solutions of the present disclosure and form a part of the specification, and are used to explain the technical solutions of the present disclosure together with embodiments of the present disclosure, and not intended to form limitations on the technical solutions of the present disclosure. Shapes and sizes of components in the drawings do not reflect actual scales, and are only intended to schematically illustrate contents of the present disclosure.

FIG. 1 is a schematic diagram of a structure of film layers of a flexible display module according to some technologies.

FIG. 2 is a schematic diagram of a structure of film layers of a flexible display module according to some exemplary embodiments.

FIG. 3a is a schematic diagram of a planar structure of a rigid material layer in FIG. 2 in some exemplary embodiments.

FIG. 3b is a schematic diagram of a planar structure of a rigid material layer in FIG. 2 in some other exemplary embodiments.

FIG. 4 is a schematic diagram of a structure of the flexible display module of FIG. 2 after a carbonized region is formed on at least one edge of the flexible display module.

FIG. 5 is a schematic diagram of an electrostatic conduction of the flexible display module of FIG. 1.

FIG. 6 is a schematic diagram of a structure of film layers of a flexible display module according to some other exemplary embodiments.

FIG. 7 is a schematic diagram of a partial structure of the flexible display module of FIG. 1 in a folded state.

FIG. 8 is a schematic diagram of a stress distribution of a film layer when a flexible display module is bent.

FIG. 9a is a schematic diagram of a structure of the flexible display module of FIG. 6 in an inward folded state.

FIG. 9b is a schematic diagram of a structure of the flexible display module of FIG. 6 in an outward folded state.

FIG. 10 is a schematic diagram of a structure of the flexible display module of FIG. 6 after a carbonized region is formed on at least one edge of the flexible display module.

### DETAILED DESCRIPTION

Those of ordinary skills in the art should understand that modifications or equivalent replacements may be made to the technical solutions of the embodiments of the present disclosure without departing from the spirit and scope of the technical solutions of the embodiments of the present disclosure, and should all fall within the scope of the claims of the present disclosure.

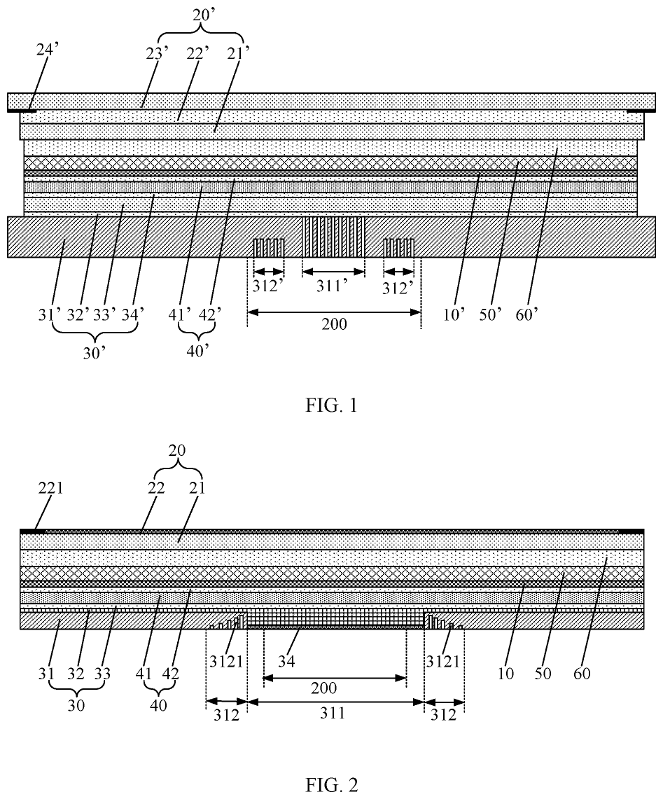

As shown in FIG. 1, FIG. 1 is a schematic diagram of a structure of film layers of a flexible display module according to some technologies, the flexible display module includes a bending region 200 and non-bending regions located on two sides of the bending region 200, and the flexible display module can be folded and unfolded by bending of the bending region 200. When the flexible display module is in a folded state, the bending region 200 is in a bent shape, and when the flexible display module is in an unfolded state, the bending region 200 is in a flattened shape. The flexible display module includes a flexible display substrate 10′, a polarizer (POL) 50′ and a cover layer 20′ which are sequentially stacked on a display side of the flexible display substrate 10′, and a support layer 30′ which is provided on a side of the flexible display substrate 10′ facing away from the display side. Herein, the flexible display substrate 10′ includes a flexible substrate and a driving circuit layer and a light emitting device which are sequentially stacked on the flexible substrate. The driving circuit layer includes a pixel driving circuit and a signal line such as a gate line and a data line, and the pixel driving circuit may include multiple thin film transistors. The light emitting device may be an organic light emitting diode (OLED) and the like. The cover layer 20′ includes a first film material 21′, an adhesive layer 22′ and a second film material 23′ which are sequentially stacked in a direction away from the flexible display substrate 10′. A portion of the second film material 23′ facing a surface of the flexible display substrate 10′ close to the edge is provided with a black material coating 24′, and the black material coating 24′ plays a shielding role. The first film material 21′ is made of colorless polyimide (CPI), ultra-thin glass (UTG) or polyethylene terephthalate (PET). The adhesive layer 22′ is made of optically colorless adhesive (OCA), and the second film material 23′ is made of CPI or PET. The cover layer 20′ is bonded to the polarizer 50′ through an adhesive layer 60′, and the adhesive layer 60′ is OCA. A back film 40′ is attached to a surface of the flexible display substrate 10′ facing away from the display side. The back film 40′ includes a third film material 41′ and an adhesive layer 42′ provided on a surface of the third film material 41′ facing the flexible display substrate 10′. The third film material 41′ is made of polyimide (PI) or PET, and the adhesive layer 42′ is made of pressure sensitive adhesive (PSA). The support layer 30′ includes an adhesive layer 32′, a fourth film material 33′, and an adhesive layer 34′ stacked sequentially on a surface of a rigid material layer 31′ facing the flexible display substrate 10′. The adhesive layer 32′ is made of stainless steel (SUS), the adhesive layer 32′ and the adhesive layer 34′ are both made of PSA or OCA, the fourth film material 33′ is made of PET or PI, and the support layer 30′ is bonded to the third film material 41′ of the back film 40′ through the adhesive layer 34′. In the bending region 200, the rigid material layer 31′ is provided with a through-hole region 311′ and half-etched regions 312′ located on two sides of the through-hole region 311′. The through-hole region 311′ is provided with multiple through-holes, the half-etched region 312′ is provided with multiple grooves located on a surface of the rigid material layer 31′ facing away from the flexible display substrate 10′, and a depth of the groove is half of a thickness of the rigid material layer 31′. The through-hole region 311′ may improve a bending ability of the rigid material layer 31′ in the bending region 200, but a pattern of the through-hole region 311′ may cause poor die printing, moreover, the flexible display module is prone to poor crease at a junction between the half-etched region 312′ and a non-bending region.

In the flexible display module of FIG. 1, after a long term use, a surface of the cover layer 20′ is prone to dents, the bending region 200 is prone to die printing, and a border area between the bending region 200 and a non-bending region is prone to creases, which affects the user experience. In addition, when the third film material 41′ in the back film 40′ is made of PET material, static electricity is prone to accumulation, and the static electricity cannot be effectively released, which leads to a characteristic deviation of a thin film transistor in the flexible display substrate 10′ and causes a problem of low gray scale greening. Because UTG and other supporting film materials are used in the cover layer 20′, in order to avoid the UTG and other supporting film materials from being bumped by the outside and causing brittle cracks, an edge of a surface film layer of the cover layer 20′ is generally provided to be protruded, and because the film layers of the flexible display module are stacked thickly, it is impossible to realize a one-piece cutting of the whole film layer, resulting in a wide bezel of the flexible display module, a complex module process and a high process cost.

An embodiment of the present disclosure provides a flexible display module, in some exemplary embodiments, as shown in FIG. 2, FIG. 2 is a schematic diagram of a structure of film layers of a flexible display module according to some exemplary embodiments, the flexible display module includes a bending region 200 and non-bending regions located at two sides of the bending region 200. The flexible display module is folded and unfolded by bending of the bending region 200, and a bending axis of the bending region 200 extends in a first direction (perpendicular to a paper surface direction in FIG. 2). The flexible display module includes a flexible display substrate 10, a cover layer 20 provided on a display side of the flexible display substrate 10, and a support layer 30 provided on a side of the flexible display substrate 10 facing away from the display side. The cover layer 20 includes a first flexible film material 21 and a first graphene layer 22 provided on a surface of the first flexible film material 21 facing away from the flexible display substrate 10. The support layer 30 includes a rigid material layer 31 and a first flexible material layer 32. The rigid material layer 31 includes a hollowed region 311 and non-hollowed regions on two sides of the hollowed region 311. In a direction perpendicular to the first direction, a width of the hollowed region 311 is larger than a width of the bending region 200, and the first flexible material layer 32 is provided on a surface of the rigid material layer 31 facing the flexible display substrate 10 and filled in the hollowed region 311.

In the flexible display module of the embodiment of the present disclosure, the cover layer 20 includes the first flexible film material 21 and the first graphene layer 22 disposed on the surface of the first flexible film material 21 facing away from the flexible display substrate 10, compared with the cover layer structure in FIG. 1, with the first graphene layer 22 used, as the graphene layer has a high mechanical strength, and the graphene layer can be designed to be very thin, the cover layer 20 structure in the embodiment of the present disclosure may replace the cover layer structure composed of the first film material 21′, the adhesive layer 22′, and the second film material 23′ in FIG. 1, the number of film layers and the thickness of the cover layer 20 may be reduced, the film layer structure of the cover layer 20 may be simplified, the peeling problem between the film layers of the cover layer 20 may be prevented in a bending process, and the bending performance may be greatly improved by combining the characteristics of graphene that is more suitable for bending. In addition, due to excellent optical properties of graphene, a transmittance is extremely high, and graphene has excellent mechanical properties, not only bendability, but also high strength, which can completely meet the requirements of a high hardness, a high light transmittance, scratch resistance and the like. In addition, due to the excellent mechanical properties of graphene, the mechanical strength of the cover layer 20 can be improved, surface scratch resistance of the cover layer 20 can be improved, and the crease problem of the cover layer in some technologies can be greatly improved.

In the flexible display module of the embodiment of the present disclosure, the support layer 30 includes a rigid material layer 31 and a first flexible material layer 32. The rigid material layer 31 includes a hollowed region 311 and non-hollowed regions on two sides of the hollowed region 311. In a direction perpendicular to the bending axis of the bending region 200, the width of the hollowed region 311 is larger than the width of the bending region 200, and the first flexible material layer 32 is provided on the surface of the rigid material layer 31 facing the flexible display substrate 10 and filled in the hollowed region 311. Compared with the support layer structure of FIG. 1, since the rigid material layer 31 is provided with the hollowed region 311 at a position corresponding to the bending region 200, and the first flexible material layer 32 may play a buffering role, the bending region 200 is not influenced by the pattern of the through-hole region and the pattern of the half-etched regions, and the bending region 200 does not have problems of die printing and crease.

Herein, the graphene layer refers to a film layer containing a graphene material, that is, the graphene layer may also contain a material other than the graphene material.

In some exemplary embodiments, as shown in FIG. 2, the material of the rigid material layer 31 may be stainless steel, and the material of the first flexible material layer 32 may be foam. In this embodiment, the rigid material layer 31 is made of stainless steel, so that the supporting and heat dissipation ability of the support layer 30 may be improved. The material of the first flexible material layer 32 is foam, which can improve the buffer capacity of the first flexible material layer 32.

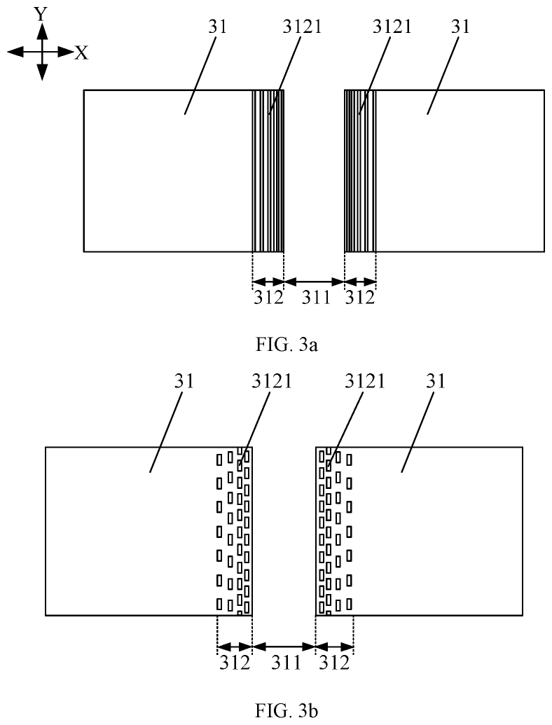

In some exemplary embodiments, as shown in FIG. 2 and FIG. 3a, FIG. 3a is a schematic diagram of a planar structure of the rigid material layer in FIG. 2 in some exemplary embodiments, a non-hollowed region may include an etched region 312 provided close to the hollowed region 311, the etched region 312 includes multiple grooves 3121 provided on the surface of the rigid material layer 31 facing away from the flexible display substrate 10. A depth or/and an arrangement density of the multiple grooves 3121 gradually decreases in a direction away from the hollowed region 311.

In this embodiment, an etched region 312 is provided in an edge area near the hollowed region 311 of the non-hollowed region, and the depth or/and the arrangement density of multiple grooves 3121 in the etched region 312 gradually decreases in etched direction away from the hollowed region 311, so that a crease problem of the flexible display module caused by a segment difference at the junction of the hollowed region 311 and the non-hollowed region can be prevented. In addition, with the structural design of the first graphene layer 22 on the surface of the cover layer 20, since the mechanical strength of the first graphene layer 22 is higher, the crease problem of the flexible display module caused by the segment difference at the junction between the hollowed region 311 and the non-hollowed region can be better avoided.

In an example of this embodiment, as shown in FIG. 3a, the shape of the grooves 3121 may be rectangular. A length direction of each groove 3121 may be parallel to the first direction (Y direction), the first direction may be parallel to a width direction of the rigid material layer 31, and both ends of the groove 3121 may extend to two opposite side edges (in this example, two long side edges of the rigid material layer 31) of the rigid material layer 31. Exemplarily, a width of the groove 3121 in a direction perpendicular to the first direction (X direction) may be 500 um to 900 um, and a spacing between two adjacent grooves 3121 may be 200 um to 800 um.

In an example of this embodiment, as shown in FIG. 2, a thickness of the rigid material layer 31 is d, and depths of the multiple grooves 3121 are 2d/6 to 5d/6, for example, depths of the grooves 3121 are sequentially 5d/6, 4d/6, 3d/6, 2d/6 in a direction away from the hollowed region 311. As shown in FIG. 3a, the spacing between two adjacent said grooves 3121 may be 800 um, 500 um, 300 um, 200 um sequentially. In this example, the depths and the arrangement density of the multiple grooves 3121 gradually decrease in the direction away from the hollowed region 311. In other embodiments, the depths of the multiple grooves 3121 may gradually decrease in the direction away from the hollowed region 311, and the arrangement density of the multiple grooves 3121 may not be changed. Alternatively, the arrangement density of the multiple grooves 3121 may gradually decrease and the depths of the multiple grooves 3121 may not be changed in a direction away from the hollowed region 311. In this example, the thickness d of the rigid material layer 31 may be 30 um to 50 um, whereas the thickness of the rigid material layer 31′ in a scheme in FIG. 1 needs to be 150 um to 200 um.

In another example of this embodiment, as shown in FIG. 3b, FIG. 3b is a schematic diagram of a planar structure of the rigid material layer in FIG. 2 in some other exemplary embodiments, the non-hollowed region may include an etched region 312 provided close to the hollowed region 311, and the etched region 312 includes multiple grooves 3121 provided on the surface of the rigid material layer 31 facing away from the flexible display substrate 10. The depths or/and the arrangement density of the multiple grooves 3121 gradually decrease in a direction away from the hollowed region 311. In this example, the shape of the groove 3121 may be rectangular, circular, oval, hexagonal, and the like, and the shape(s) of the grooves 3121 is not limited in this example. A change range of the depths of the multiple grooves 3121 may vary from 2d/6 to 5d/6, where d is the thickness of the rigid material layer 31.

In some exemplary embodiments, as shown in FIG. 2 and FIG. 3a, the rigid material layer 31 may be broken into two parts at the hollowed region 311, the hollowed region 311 is located in the bending region 200 and may be partially located in two non-bending regions on the two sides of the bending region 200, i.e. the hollowed region 311 may be provided beyond the bending region 200. In this way, the rigid material layer 31 does not have any etching pattern at the position corresponding to the bending region 200, thus avoiding the die printing problem of the bending region 200. Moreover, the hollowed region 311 is provided beyond the bending region 200, thus avoiding the problem of poor crease at the junctions between the half-etched region 312′ and the non-bending regions of the flexible display module of FIG. 1.

In some exemplary embodiments, as shown in FIG. 2, a thickness of a portion of the first flexible material layer 32 corresponding to the position of the hollowed region 311 is greater than a thickness of the remaining portions. A third graphene layer 34 is provided on a surface of a portion of the first flexible material layer 32 filled in the hollowed region 311 away from the flexible display substrate 10.

In this embodiment, the arrangement of the third graphene layer 34 may improve the bending performance of the bending region 200. In addition, with the first graphene layer 22 on a surface of the cover layer 20, as the thickness of a graphene layer itself can be designed to be very thin because the graphene layer has a high mechanical strength, and a design thickness of the rigid material layer 31 in the support layer 30 may be reduced, thus reducing material cost of the rigid material layer 31. In addition, graphene also has a strong heat dissipation capability, which can improve a heat dissipation capability of the flexible display module, prevent problems such as heating and aging of the flexible display module, and reduce high temperature reliability risk of the flexible display module.

In this embodiment, a surface of the portion of the first flexible material layer 32 filled in the hollowed region 311 away from the flexible display substrate 10 may be lower than a surface of the non-hollowed region of the rigid material layer 31 away from the flexible display substrate 10, thereby preventing the first flexible material layer 32 from protruding and affecting the bending region 200.

In some exemplary embodiments, as shown in FIG. 2, a surface of the flexible display substrate 10 facing away from the display side is attached with a back film 40. The back film 40 includes a second flexible film material 41 and a first adhesive layer 42 provided on a surface of the second flexible film material 41 facing the flexible display substrate 10. The first adhesive layer 42 is adhered to the surface of the flexible display substrate 10 away from the display side. A material of the second flexible film material 41 is polyethylene terephthalate (PET). Exemplarily, a material of the first adhesive layer 42 may be PSA.

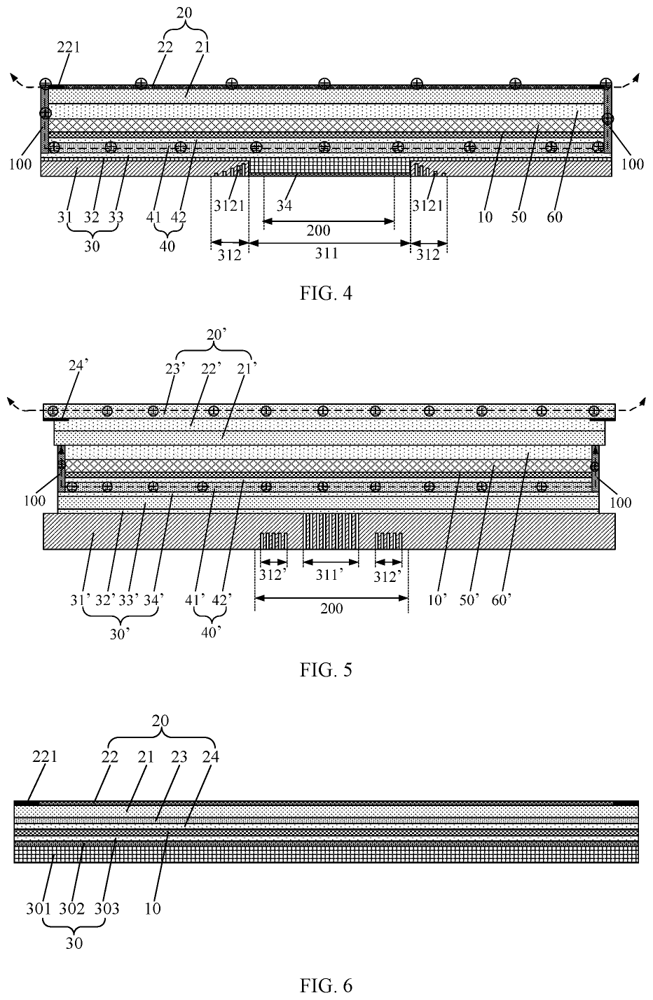

In an example of this embodiment, as shown in FIG. 4, FIG. 4 is a schematic diagram of a structure of the flexible display module of FIG. 2 after a carbonized region is formed on at least one edge of the flexible display module, at least one edge of all film layers of the flexible display module is flush provided and formed by laser integrated cutting, the second flexible film material 41 in the flexible display module and portions of all film layers of the second flexible film material 41 on a side away from the rigid material layer 31 close to the flush-provided edges are carbonized and a carbonized region 100 is formed in a laser integrated cutting process.

As shown in FIG. 5, FIG. 5 is a schematic diagram of an electrostatic conduction of the flexible display module of FIG. 1, as UTG and other supporting film materials are used in the cover layer 20′, in order to avoid UTG and other supporting film materials from being bumped by the outside, which may initiate brittle cracking, an edge of a surface film layer of the cover layer 20′ is generally provided to be protruded, and because the film layers of the flexible display module are stacked to be thicker, it is impossible to cut the entirety of the film layers in an integral cutting, only a portion of the film layer (the film layers between the cover layer 20′ and the rigid material layer 31′ of the support layer 30′) can be cut by laser integrated cutting to form a flush edge, the portion of the film layers close to the flush edge of the laser cutting may be form with a carbonized region 100 (the carbonized region 100 has a stronger ability of conducting static electricity than a non-carbonized region). The carbonized region 100 is connected with the third film material 41′ (PET or PI material, and it is easy to accumulate static electricity when PET material is used) of the back film 40′. However, the carbonized region 100 cannot be connected with a surface film layer of the cover layer 20′, thus an electrostatic conduction loop cannot be formed, in this way, in practical application, an edge portion of the surface film layer of the cover layer 20′ is connected with the whole machine casing of a display device, the static electricity accumulated in the third film material 41′ of the back film 40′ cannot be conducted through the carbonized region 100 to the surface film layer of the cover layer 20′ connected with the whole machine casing, so that the static electricity accumulated in the third film material 41′ cannot be released, and the characteristics of the thin film transistors in the flexible display substrate 10′ are shifted, resulting in problems such as low gray scale greening and the like.

In this embodiment, as shown in FIG. 4, a material of the second flexible film material 41 of the back film 40 is PET, because of the second flexible film material 41 in the flexible display module, and a portion of the entirety of film layers of the second flexible film material 41 on a side away from the rigid material layer 31 close to the flush-provided edges are carbonized in a laser integrated cutting process and a carbonized region 100 is formed. The carbonized region 100 can form an electrostatic conduction loop with the second flexible film material 41 made of PET and the first graphene layer 22 on the surface of the cover layer 20, in practical application, an edge portion of the first graphene layer 22 on a surface of the cover layer 20 of the flexible display module may be connected with a whole machine casing of the display device, thus static electricity generated by the second flexible film material 41 and all the film layers on a side of the second flexible film material 41 away from the rigid material layer 31 may be transmitted to the whole machine casing (the whole machine casing is grounded) through the static electricity conduction loop and be released, which may greatly improve an anti-static ability of the flexible display module, and avoid the problem of low gray scale greening caused by static electricity accumulation of the flexible display module. As a result, it is not easy to accumulate static electricity which causes side effects when the second flexible film material 41 is made of PET material, and because the first graphene layer 22 on the surface of the cover layer 20 has excellent electrical properties, the second flexible film material 41, the first graphene layer 22, and the carbonized region 100 can jointly form the electrostatic conduction loop to release static electricity, which can greatly improve the anti-static ability of the flexible display module. In addition, cost of a PET material is lower than cost of a PI material, which is beneficial to reducing costs of the flexible display module.

In this embodiment, since the use of a supporting film material such as UTG is eliminated in the film layers of the cover layer 20, an edge of the surface film layer of the cover layer 20 does not need to be provided to be protruded to protect the supporting film material such as UTG, and at least one edge of all the film layers of the flexible display module can be flush provided and formed by laser integrated cutting, so that a module process can be simplified, process costs can be reduced, and a bezel width of the flexible display module can be reduced.

In some exemplary embodiments, as shown in FIG. 2, the support layer 30 further includes a second adhesive layer 33 provided on a surface of the first flexible material layer 32 facing away from the rigid material layer 31, and the first flexible material layer 32 is bonded to the back film 40 through the second adhesive layer 33.

In this embodiment, the first flexible material layer 32 and the second adhesive layer 33 in the support layer 30 are used to replace the adhesive layer 32′, the fourth film material 33′, and the adhesive layer 34′ in the support layer 30′ of FIG. 1. Reducing the number of stacked layers of the support layer 30 can improve the interlayer peeling problem of the support layer 30′ of FIG. 1, reduce the problems of complex stress, design difficulty, complicated verification laboratory and the like caused by a large number of layers that are stacked, and is beneficial to simplifying design and experiment, and greatly reducing verification costs.

Exemplarily, a material of the second adhesive layer 33 may be PSA, and a thickness of the second adhesive layer may be less than or equal to 15 um. A material of the first flexible material layer 32 may be foam, a thickness of a portion of the first flexible material layer 32 corresponding to a position of the non-hollowed region of the rigid material layer 31 may be less than or equal to 30 um, and a thickness of a portion of the first flexible material layer 32 corresponding to a position of the hollowed region 311 of the rigid material layer 31 may be less than or equal to 80 um.

In some exemplary embodiments, as shown in FIG. 2, the flexible display module may further include a polarizer 50 provided between the flexible display substrate 10 and the cover layer 20. One side surface of the polarizer 50 is bonded to the first flexible film material 21 by a third adhesive layer 60, and the other side surface of the polarizer 50 is bonded to a surface (display surface) of the flexible display substrate 10 facing away from the support layer 30. Exemplarily, the polarizer 50 may include a polyvinyl alcohol (PVA) film, a cellulose triacetate (TAC) film, and a PSA layer which are sequentially stacked, the PSA layer is bonded to the display surface of the flexible display substrate 10, and the PVA film is bonded to the first flexible film material 21 through the third adhesive layer 60. A material of the third adhesive layer 60 may be OCA.

In some exemplary embodiments, as shown in FIG. 2, a material of the first flexible film material 21 may be colorless polyimide (CPI) or PET. The first graphene layer 22 may be made of a mixed compound including graphene, an organic nonpolar solvent and acrylate, which can be well adhered to a surface of CPI or PET material and hardened, and a thickness of the first graphene layer 22 may be less than 5 um.

In some exemplary embodiments, as shown in FIG. 2, a portion of the first graphene layer 22 close to an edge may be doped with a black material 221. Exemplarily, the black material 221 may be graphite powder, black pigment, or the like. The black material 221 may play a shielding role.

In the scheme of FIG. 1, a black material coating 24′ is provided on an inner side edge of the second film material 23′, which will lead to a height difference between an edge area and a non-edge area of the cover layer 20′, which is easy to cause poor peeling between the film layers during a bending process. In this embodiment, the black material 221 is doped on a portion close to an edge of the first graphene layer 22, thereby avoiding a segment problem, so as to improve a bending performance and prevent a bending peeling problem.

In some other exemplary embodiments of an embodiment of the present disclosure, as shown in FIG. 6, FIG. 6 is a schematic diagram of a structure of film layers of a flexible display module according to some other exemplary embodiments, the flexible display module includes a flexible display substrate 10, a cover layer 20 provided on a display side of the flexible display substrate 10, and a support layer 30 provided on a side away from the display side of the flexible display substrate 10. The cover layer 20 includes a first flexible film material 21 and a first graphene layer 22 provided on a surface of the first flexible film material 21 facing away from the flexible display substrate 10. The support layer 30 includes a second flexible material layer 301 and a second graphene layer 302, wherein the second graphene layer is provided on a surface of the second flexible material layer 301 facing the flexible display substrate 10.

In this embodiment, the support layer 30 includes the second flexible material layer 301 and the second graphene layer 302 provided on the surface of the second flexible material layer 301 facing the flexible display substrate 10. Compared with a structure of the support layer 30′ in FIG. 1, the rigid material layer 31′ is eliminated, and a stacked design of the second flexible material layer 301 and the second graphene layer 302 is adopted. Because of a high mechanical strength and heat dissipation capability of graphene, supporting and heat dissipation requirements of the flexible display module can be fully met.

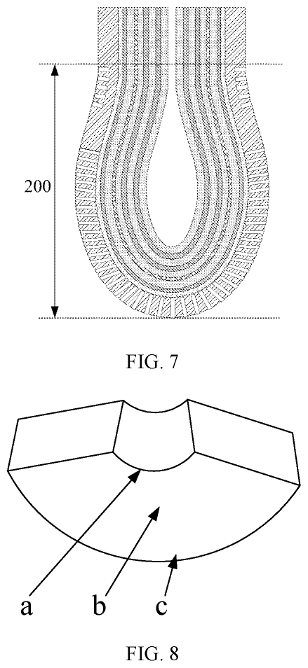

In addition, as shown in FIG. 1 and FIG. 7, FIG. 7 is a schematic diagram of a partial structure of the flexible display module of FIG. 1 in a folded state. Since a rigid material layer 31′ is used in the support layer 30′ of the flexible display module of FIG. 1, the flexible display module of FIG. 1 can only be bent at the bending region 200 when being folded. In this embodiment, since the rigid material layer is removed from the support layer 30, it can break through the design that the flexible display module can only be bent in a fixed area (the bending region 200 in FIG. 1), and whole area bending of the flexible display module (that is, any area of the whole area of the flexible display module can be bent) can be realized, and can be bent transversely and longitudinally, and can be bent inward and outward, with a better bending performance.

As shown in FIG. 8, FIG. 8 is a schematic diagram showing a stress distribution of the film layer when the flexible display module is bent. When the flexible display module is bent, an inner film layer a is compressed to generate compressive stress, an outer film layer c is stretched to generate tensile stress (tensional stress), and some middle film layers b are neutral layers (neither stretched nor compressed, and the stress is zero). In the flexible display module, a position of a neutral layer is affected by a film structure, a film thickness and a bending radius of the flexible display module. In order to avoid the damage to the light emitting devices in the flexible display substrate during bending, the flexible display substrate can be placed in a neutral layer when it is bent during the design of a film layer structure of the flexible display module.

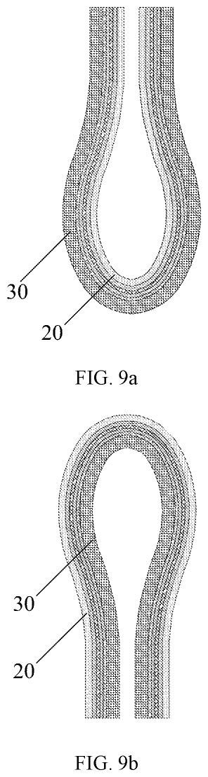

As shown in FIG. 6, FIG. 9a and FIG. 9b, FIG. 9a is a schematic diagram of a structure of the flexible display module of FIG. 6 in an inward folded (the display side of the flexible display module is on the inside) state, FIG. 9b is a schematic diagram of a structure of the flexible display module of FIG. 6 in an outward folded (the display side of the flexible display module is on the outside) state. The flexible display module of this embodiment can be folded inwardly and outwardly when being bent, and the flexible display module is in a shape of a water droplet after being folded inwardly or outwardly. In order to avoid the damages to a light emitting device in the flexible display substrate during a bending process, the flexible display substrate can be placed in a neutral layer during bending in the design of a film layer structure of the flexible display module. When the flexible display module of this embodiment is inwardly folded, the first graphene layer 22 on a surface of the cover layer 20 can release the compressive stress of the inner film layer, and the second graphene layer 302 in the support layer 30 can release the tensile stress of the outer film layer, so that a bending performance of the flexible display module can be greatly improved, the existing bending level can be broken through, the times of bending at normal temperature can reach more than 200 thousand times, and the bending radius is less than 1.5 mm.

In an example of this embodiment, as shown in FIG. 6, the cover layer 20 may further include a polarizing film 23 provided on a side of the first flexible film material 21 facing the flexible display substrate 10, and a fourth adhesive layer 24 provided on a side of the polarizing film 23 facing the flexible display substrate 10. The fourth adhesive layer 24 is bonded to the display surface of the flexible display substrate 10.

Exemplarily, the polarizing film 23 may be a polyvinyl alcohol (PVA) film with a thickness of 5 um to 10 um. The first flexible film material 21 may be made of CPI or PET material, and a thickness of the first flexible film material 21 may be 30 um to 50 um. The fourth adhesive layer 24 may be PSA and may have a thickness of 15 um to 25 um.

Compared with the scheme in FIG. 1, in this example, the polarizing film 23 is provided in the cover layer 20, the polarizer 50′ in FIG. 1 (the polarizer 50′ is a composite film layer including a PVA film, a cellulose triacetate (TAC) film and a PSA film) is cancelled, and the fourth adhesive layer 24 is employed in the cover layer 20, the adhesive layer 60′ in FIG. 1 is cancelled, since the polarizer 50′ and the adhesive layer 60′ in FIG. 1 are removed, a laminated thickness of the flexible display module can be reduced, thus simplifying bending design, simulation and verification experiments, and reducing verification costs and product costs of the flexible display module. In addition, due to the reduced stacked thickness of the flexible display module, combined with the excellent mechanical bending ability of the graphene layer, the bending performance of the flexible display module can be improved. In addition, since the first graphene layer 22 is provided on the surface of the cover layer 20, the heat dissipation ability of the graphene layer is extremely strong, which can improve the resistance of the PVA film to high temperature and high humidity and reduce the reliability risk.

In an example of this embodiment, as shown in FIG. 6, the support layer 30 further includes a fifth adhesive layer 303 provided on a side of the second graphene layer 302 facing the flexible display substrate 10, and the fifth adhesive layer 303 is bonded to a surface of the flexible display substrate 10 on a side facing away from the display side.

Exemplarily, a material of the second flexible material layer 301 may be foam and a thickness may be 60 um to 80 um. A thickness of the second graphene layer 302 may be less than 5 um. The fifth adhesive layer 303 may be PSA and may have a thickness of 15 um to 30 um.

In this example, the fifth adhesive layer 303 of the support layer 30 is directly bonded to a surface of the flexible display substrate 10 facing away from the display side, compared with the scheme in FIG. 1, the back film 40′ in FIG. 1 is removed, so that problems such as crushing and scratching caused by external forces such as foreign bodies and platforms on the flexible display substrate 10 in a module process will not be increased, and the supporting and protection ability for the flexible display substrate 10 can be improved due to an extremely high strength of the second graphene layer 302 in the support layer 30. In addition, the rigid material layer 31 is not provided in the support layer 30 in this example, and the film layer of the support layer 30 can be attached with a layer of incoming material, which can reduce the process steps and costs, and can save a relatively expensive metal used, such as a titanium alloy contained in the rigid material layer 31, thus reducing the cost.

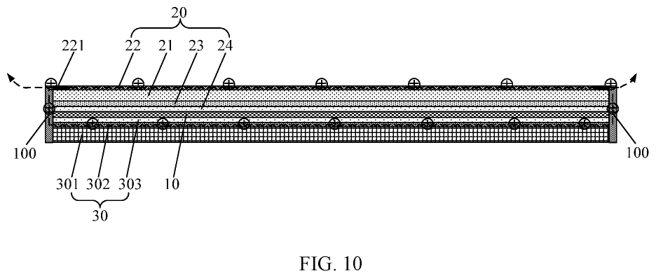

In an example of this embodiment, as shown in FIG. 10, FIG. 10 is a schematic diagram of a structure of the flexible display module of FIG. 6 after a carbonized region is formed on at least one edge of the flexible display module, at least one edge of all the film layers of the flexible display module is flush-provided and can be formed by laser integrated cutting, and portions of all the film layers of the flexible display module close to the flush-provided edge are carbonized in a process of laser integrated cutting to form a carbonized region 100.

In this embodiment, at least one edge of all the film layers of the flexible display module can be formed by laser integrated cutting, which can simplify the module process and reduce the process cost, and an edge attachment accuracy of the film layer of the flexible display module can reach below 50 um, which is beneficial to improving the quality and stability of the flexible display module. A portion of all the film layers of the flexible display module close to the flush-provided edge is carbonized in a laser integrated cutting process to form the carbonized region 100, The carbonized region 100 may form an electrostatic conduction loop with the second graphene layer 302 in the support layer 30 and the first graphene layer 22 on a surface of the cover layer 20, in practical application, as the edge portion of the first graphene layer 22 on the surface of the cover layer 20 of the flexible display module is connected with the whole machine casing of the display device (the whole machine casing is grounded), in this way, the static electricity generated by all the film layers in the flexible display module can be transmitted to the whole machine casing through the static electricity conduction loop and be released, which can greatly improve the anti-static ability of the flexible display module and avoid the problem of low gray scale greening caused by static electricity accumulation of the flexible display module. The fifth adhesive layer 303 can be made of PSA, in the PSA, halogen element doping can be eliminated, and polymer doping containing benzene ring group, such as poly (tert-butyl 2-ethylphenylacrylate), can be increased. The polymer containing benzene ring group has better stability, which is not easily affected by external static electricity, thus the release of free traveling ions can be reduced, and the electrical disturbance of the second graphene layer 302 can be well isolated.

A display device is further provided in an embodiment of the present disclosure, which includes the flexible display module described in any of the aforementioned embodiments. Exemplarily, the display device may be a foldable display device, such as a foldable mobile phone, a foldable tablet computer, or the like.

In the accompanying drawings, a size of a constituent element, and a thickness of a layer or a region are sometimes exaggerated for clarity. Therefore, an implementation of the present disclosure is not necessarily limited to the size, and a shape and a size of each component in the drawings do not reflect an actual scale. In addition, the drawings schematically illustrate some examples, and an implementation of the present disclosure is not limited to the shapes or numerical values shown in the drawings.

In the description herein, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the description herein, orientation or position relationships indicated by the terms such as “upper”, “lower”, “left”, “right”, “top”, “inside”, “outside”, “axial”, “tetragonal” and the like are orientation or position relationships shown in the drawings, and are intended to facilitate description of the embodiments of the present disclosure and simplification of the description, but not to indicate or imply that the mentioned structure has a specific orientation or be constructed and operated in a specific orientation, therefore, they should not be understood as limitations on the present disclosure.

In the description herein, unless otherwise specified and defined explicitly, terms “connection”, “fixed connection”, “installation” and “assembly” should be understood in a broad sense, and, for example, “connection” may be a fixed connection, a detachable connection or an integrated connection; the terms “installation”, “connection” and “fixed connection” may be a direct connection, an indirect connection through intermediate components, or an inner communication between two components. For those ordinarily skilled in the art, meanings of the above terms in the embodiments of the present disclosure may be understood according to situations.

1. A flexible display module, comprising a bending region and non-bending regions located on two sides of the bending region, wherein the flexible display module is folded and unfolded by bending of the bending region, and a bending axis of the bending region extends along a first direction;
the flexible display module comprises a flexible display substrate, a cover layer provided on a display side of the flexible display substrate, and a support layer provided on a side of the flexible display substrate facing away from the display side;
the cover layer comprises a first flexible film material and a first graphene layer provided on a surface of the first flexible film material facing away from the flexible display substrate;
the support layer comprises a rigid material layer and a first flexible material layer, the rigid material layer comprises a hollowed region and non-hollowed regions located on two sides of the hollowed region, in a direction perpendicular to the first direction, a width of the hollowed region is larger than a width of the bending region, and the first flexible material layer is provided on a surface of the rigid material layer facing the flexible display substrate and filled in the hollowed region; or, the support layer comprises a second flexible material layer and a second graphene layer provided on a surface of the second flexible material layer facing the flexible display substrate.

2. The flexible display module according to claim 1, wherein the rigid material layer is broken into two portions in the hollowed region, and the hollowed region is located in the bending region and is partially located in the two non-bending regions located on the two sides of the bending region.

3. The flexible display module according to claim 1, wherein a non-hollowed region comprises an etched region provided close to the hollowed region, and the etched region comprises a plurality of grooves provided on a surface of the rigid material layer facing away from the flexible display substrate; depths or/and an arrangement density of the plurality of grooves gradually decrease in a direction away from the hollowed region.

4. The flexible display module according to claim 3, wherein a length direction of each groove is parallel to the first direction, and two ends of the groove extend to opposite side edges of the rigid material layer; a width of the groove is 500 um to 900 um, and a spacing between two adjacent grooves is 200 um to 800 um.

5. The flexible display module according to claim 3, wherein a thickness of the rigid material layer is d, and the depths of the plurality of grooves are 2d/6 to 5d/6.

6. The flexible display module according to claim 1, wherein a third graphene layer is provided on a surface of a portion of the first flexible material layer filled in the hollowed region, with the surface facing away from the flexible display substrate.

7. The flexible display module according to claim 1, wherein a back film is attached to a surface of the flexible display substrate facing away from the display side; the back film comprises a second flexible film material and a first adhesive layer provided on a surface of the second flexible film material facing the flexible display substrate, and the first adhesive layer is bonded to a surface of the flexible display substrate facing away from the display side; the material of the second flexible film material is polyethylene terephthalate.

8. The flexible display module according to claim 7, wherein the support layer further comprises a second adhesive layer provided on a surface of the first flexible material layer facing away from the rigid material layer, and the first flexible material layer is bonded to the back film by the second adhesive layer.

9. The flexible display module according to claim 7, at least one edge of all film layers of the flexible display module is provided to be flush and formed by laser integrated cutting, the second flexible film material in the flexible display module, and portions of all film layers of the second flexible film material on a side away from the rigid material layer close to the flush-provided edge are carbonized and a carbonized region is formed in a process of the laser integrated cutting.

10. The flexible display module according to claim 1, further comprising a polarizer provided between the flexible display substrate and the cover layer, one side surface of the polarizer is bonded to the first flexible film material through a third adhesive layer, and other side surface of the polarizer is bonded to a surface of the flexible display substrate facing away from the support layer.

11. The flexible display module according to claim 1, wherein a material of the first flexible film material is colorless polyimide or polyethylene terephthalate.

12. The flexible display module according to claim 1, wherein the cover layer further comprises a polarizing film provided on a side of the first flexible film material facing the flexible display substrate, and a fourth adhesive layer provided on a side of the polarizing film facing the flexible display substrate; the fourth adhesive layer is bonded to a display surface of the flexible display substrate.

13. The flexible display module according to claim 1, wherein the support layer further comprises a fifth adhesive layer provided on a side of the second graphene layer facing the flexible display substrate, and the fifth adhesive layer is bonded to a surface of the flexible display substrate facing away from the display side.

14. The flexible display module according to claim 1, wherein a portion of the first graphene layer close to an edge is doped with a black material.

15. The flexible display module according to claim 1, wherein the support layer comprises a second flexible material layer and a second graphene layer provided on a surface of the second flexible material layer facing the flexible display substrate; at least one edge of all the film layers of the flexible display module is provided to be flush and formed by laser integrated cutting, and portions of all the film layers close to the flush-provided edge of the flexible display module are carbonized and a carbonized region is formed in a process of the laser integrated cutting.

16. The flexible display module according to claim 1, wherein a material of the rigid material layer is stainless steel, and a material of the first flexible material layer or the second flexible material layer is foam.

17. A display device, comprising the flexible display module according to claim 1.
